(19) United States
(12) Patent Application Publication
(10) Pub. No.: US 2017/0121846 A1
(43) Pub. Date: May 4, 2017

(54) SUSCEPTOR WITH ASYMMETRIC RECESSES, REACTOR FOR EPITAXIAL DEPOSITION AND PRODUCTION METHOD

(71) Applicant: LPE S.p.A., Baranzate (MI) (IT)

(72) Inventors: Vincenzo OGLIARI, Baranzate (MI) (IT); Silvio PRETI, Baranzate (MI) (IT); Francesco COREA, Baranzate (MI) (IT); Franco PRETI, Baranzate (MI) (IT)

(21) Appl. No.: 15/342,836

(22) Filed: Nov. 3, 2016

(30) Foreign Application Priority Data
Nov. 3, 2015 (IT) 102015000068372

(51) Int. Cl. C30B 25/12; C23C 16/458; B28B 17/00; C30B 29/06

(52) U.S. Cl. CPC C30B 25/12; C30B 29/06; C23C 16/4581; C23C 16/4584; B28B 17/0009

(57) ABSTRACT

This disclosure concerns a susceptor for a reactor for epitaxial deposition comprising a body having the shape of a horizontal disc; the body has a first upper face, a second lower face and a vertical symmetry axis of the body; the first face has a plurality of disc-shaped recesses each of which with a centroid and with a symmetry axis of the recess which passes through said centroid; a section of each of said recesses taken along any vertical plane which comprises said vertical symmetry axis of the body is asymmetric with respect to any axis; a section of each of said recesses taken along any vertical plane which is parallel to said vertical symmetry axis of the body and which is perpendicular to a radius of the body passing through the centroid of the recess is symmetric with respect to a vertical axis.

This application claims the benefit of Italian Patent Application for Invention No. 102015000068372 filed on Nov. 3, 2015, the disclosure of which is incorporated herein by reference.

### DESCRIPTION

Field of the Invention

This disclosure concerns a susceptor with asymmetrical recesses (also called “pockets”), a reactor for epitaxial deposition that comprises such a susceptor and a method for producing it.

State of the Art

In the reaction chamber of a reactor for epitaxial deposition on substrates (also called “wafers”), having a disc-shaped susceptor that is used to horizontally support one or more disc-shaped substrates and that is associated with a heating system (refer, for example, to FIG. 3), it is common practice to house the disc-shaped substrates inside recesses of the susceptor the bottom of which is suitably shaped, generally substantially in the form of a spherical cap, and the depth of which is suitable, generally comparable to the thickness of the substrates—the thickness of the susceptor is much greater than the thickness of the substrates, generally at least ten times greater.

The substrates, however, have a flat shape.

The reason why recesses are used that have a shaped bottom, in particular concave, instead of a flat one (like the substrates), is that the substrates deform during the treatment process in the reactor particularly when they are heated from a low temperature, generally room temperature (for example 20-30° C. with atmospheric pressure), to deposition temperature (for example 1050-1150° C. with substantially atmospheric pressure in the case of epitaxial deposition of monocrystalline silicon).

In particular, in the case in which the heating system of the susceptor produces a temperature gradient in the substrate such that the surface of the substrate closest to the susceptor (i.e. partially or totally in contact with the susceptor) is hotter than the surface of the substrate furthest from the susceptor (i.e. opposite), the substrate deforms and takes up a roughly spherical cap shape; such a heat gradient is generated, for example, when the heating system (often by induction and outside of the chamber) is positioned on the side of the susceptor opposite to that which houses the substrates. If the bottom of the recess that houses the substrate was flat it would produce a great lack of uniformity of heating of the substrate since the substrate would rest substantially only on the central area of the bottom of the recess.

However, in the reaction chamber of a reactor for epitaxial deposition the disc-shaped susceptor, typically made of graphite, also deforms from when it is inserted (cold) in the chamber to when the deposition onto the substrates begins (at high temperature).

The Applicant has studied this phenomenon and thinks that the substrate deforms mainly:
A) due to the thermal gradient in the vertical direction
B) due to the weight (since the temperature is high there is a certain bending due to the weight force)
C) in the case of an induction heating system positioned only on one side of the susceptor below the susceptor, due to the forces deriving from the electromagnetic field (since the temperature is high there is a certain bending due to the electromagnetic field)

D) due to tensions induced by possible coatings (in SiC and/or TaC) present on the susceptor, particularly if the thickness of material deposited on one face of the susceptor is quite different (for example by 10-20%) from the thickness of material deposited on the opposite face of the susceptor

These causes contribute differently to the deformation of the susceptor; cause A contributes to lifting the peripheral area of the susceptor; cause B contributes to slightly lowering the peripheral area of the susceptor; cause C contributes to slightly lifting the peripheral area of the susceptor; cause D can contribute in one or other direction depending on the greater thickness of material deposited on one or other face. It has been ascertained by the Applicant that the sum of all of these causes leads to a deformation of the susceptor such that its peripheral area lifts.

One of the important and undesired effects of such deformation is that the contact between substrate and susceptor (inside the recess) is not regular, causing non-uniform heating of the substrate and therefore, sometimes, crystallographic defects occur in the substrates treated by the reactor.

### SUMMARY

According to one aspect of the disclosure, a susceptor is disclosed that is suitably configured—one could say “pre-deformed”—so that when the conditions for epitaxial deposition are reached in the reaction chamber, the susceptor has deformed and its recesses have taken up a shape equal or very similar to the ideal one. Also discloses is a reactor for epitaxial deposition that comprises such a susceptor, and a possible method for producing such a susceptor in a relatively simple manner.

### LIST OF FIGURES

The disclosure will become clearer from the following detailed description to be considered together with the attached drawings, in which:

FIG. 1 shows a vertical section view of a susceptor according to the prior art,

FIGS. 2a, 2b, and 2c show three views from above of susceptor recesses according to the prior art,

FIGS. 3a and 3b illustrate a possible deformation of a susceptor according to the prior art, from which it is inserted cold into the chamber to when the deposition on the substrates begins at high temperature,

FIGS. 4a and 4b illustrate a possible deformation of a susceptor according to the disclosure, from which it is inserted cold into the chamber to when the deposition on the substrates begins at high temperature,

FIGS. 5a, 5b, 5c, 5d and 5e show five steps of a method for producing a susceptor according to the disclosure,

FIGS. 6a, 6b, and 6c show three steps of a method for producing a susceptor according to the disclosure which is a variant of the method according to FIG. 5,

FIG. 7 shows a view from above of a susceptor according to the disclosure,

FIG. 8 shows a vertical section view of a recess of the susceptor of FIG. 7 during a deposition on substrates at high temperature,

FIG. 9 shows a first vertical section view of a recess of the susceptor of FIG. 7 before being inserted cold into a reaction chamber of an epitaxial reactor, and

FIG. 10 shows a second vertical section view of a recess of the susceptor of FIG. 7 before being inserted cold into a reaction chamber of an epitaxial reactor.

As can easily be understood, there are various ways of putting into practice the disclosed embodiments defined in its main advantageous aspects in the attached claims.

### DETAILED DESCRIPTION

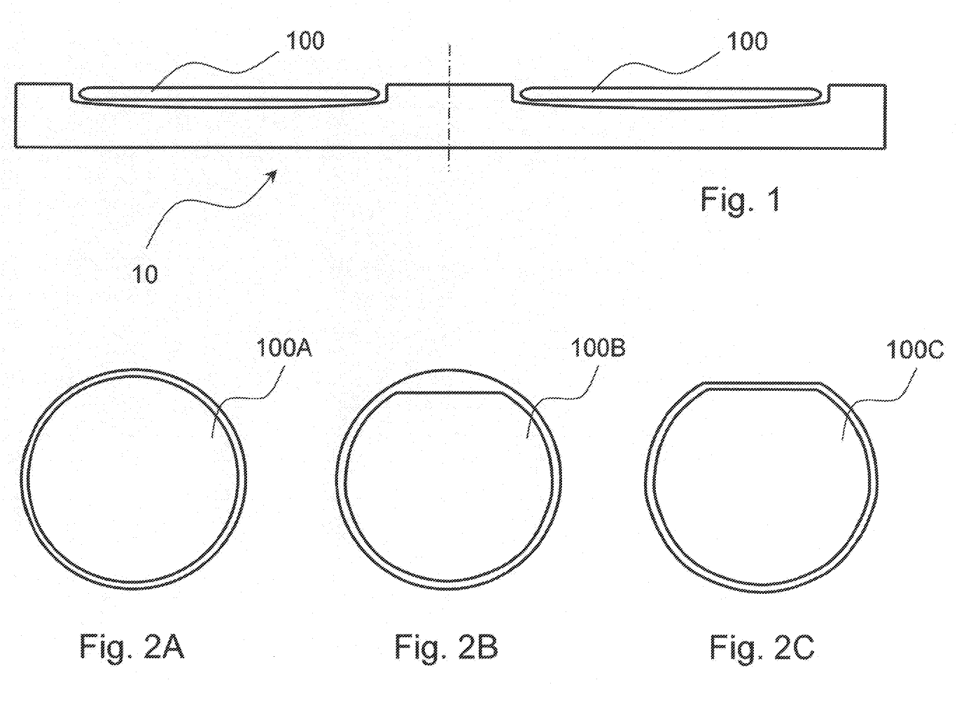

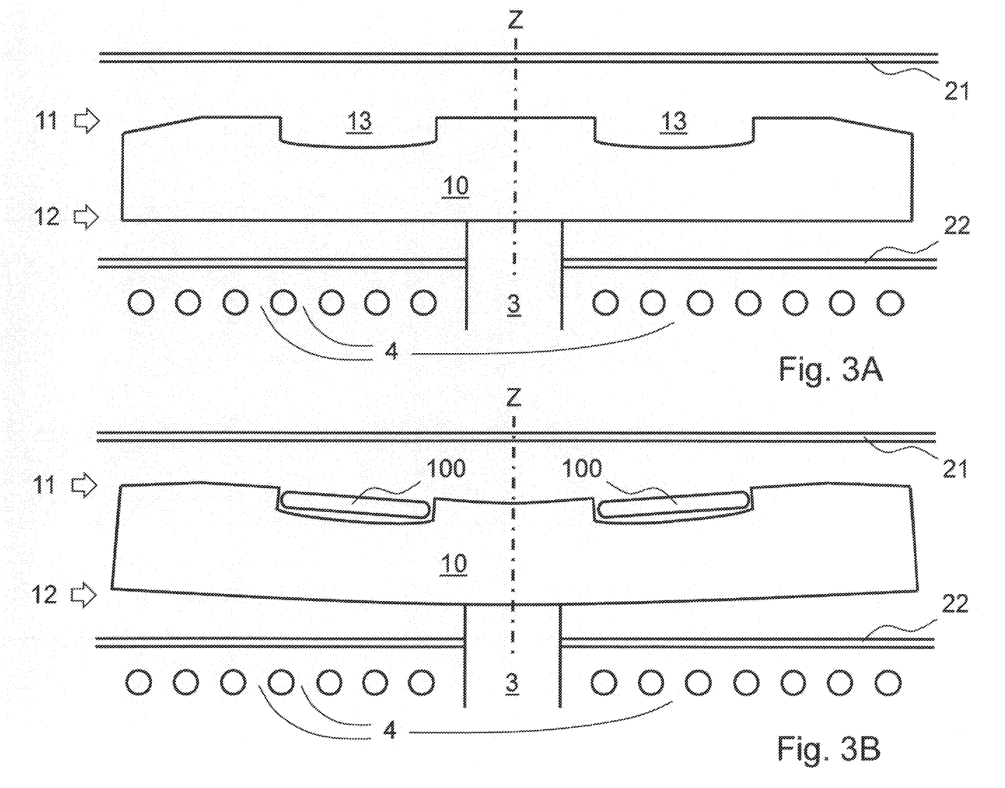

FIG. 1 shows a vertical section view of a susceptor 10 (for a reactor for epitaxial deposition), according to the prior art, which consists of a substantially cylinder-shaped (i.e. its height is comparable with its diameter) body made of graphite totally coated with SiC; the body has a first upper face 11 (see FIG. 3) that is substantially flat, a second lower face 12 (see FIG. 3) that is perfectly flat and a vertical axis Z (see FIG. 3) of substantially symmetry of the body; the first upper face has a plurality (typically between two and eight) of thin substantially disc-shaped (i.e. its height is much smaller, e.g. at least 10 times, than its diameter) recesses 13 (see FIG. 3) in which substrates 100 are housed and laid down; the recesses have a slightly concave bottom (in particular in the form of a spherical cap) and therefore, when cold, a substrate 100 touches the bottom of the recess only in an annular area.

According to the prior art, the recesses of the susceptor 10 di FIG. 1 can, for example, be as shown in FIG. 2; the recess of FIG. 2A has a perimeter shape corresponding to a circumference (i.e. it is perfectly cylindrical) and is adapted for housing an almost perfectly cylindrical substrate 100A; the recess of FIG. 2B has a perimeter shape corresponding to a circumference (i.e. it is almost perfectly cylindrical) and is designed to house a cylindrical substrate 100B with a small side “flat” (i.e. it is substantially cylindrical); the recess of FIG. 2C has a perimeter shape corresponding to a circumference with a small “flat” (i.e. it is substantially cylindrical) and is adapted for housing a cylindrical substrate 100C with a small “flat” (i.e. it is substantially cylindrical).

FIG. 3 shows the susceptor 10 of FIG. 1 inside a reaction chamber of an epitaxial reactor with “cold” walls (i.e. cooled through flows of gas and/or liquid); reference numeral 21 indicates the flat upper wall of the chamber and reference numeral 22 indicates the flat lower wall of the chamber; the susceptor 10 is mounted on a rotating shaft 3. The heating system of the susceptor 10 is by induction and is obtained through a flat inductor 4 arranged outside of the chamber under the lower wall 22 and parallel to it.

FIG. 3A shows the susceptor 10, without substrates, inside the reaction chamber at low temperature; FIG. 3B shows the susceptor 10, with substrates 100, inside the reaction chamber when the deposition on the substrates 100 begins (i.e. at high temperature) and during the deposition on the substrates 100 (i.e. at high temperature); note the deformation of the susceptor 10 and the consequent deformation (and movement) of the recesses 13 thereof described earlier; the substrates 100 also deform, as described earlier.

One of the undesired effects of the deformation of the susceptor and of the recesses thereof is that, during the deposition (FIG. 3B), the contact between substrate and susceptor (inside the recess) is not regular causing non-uniform heating of the substrate and therefore, sometimes, crystallographic defects occur in the substrates treated by the reactor.

Moreover, during deposition (FIG. 3B), the substrates are not in flat position and therefore an area thereof is closer to the upper wall of the reaction chamber and an area thereof is further from the upper wall of the reaction chamber; this can lead to both slight temperature differences and slight differences in deposition.

Finally, during the deposition (FIG. 3B), the deformed susceptor creates slight turbulence along the path of the of the gases inside the reaction chamber since the distance between susceptor and upper wall of the chamber firstly increases (to the left of the axis Z, i.e. upstream of the centre of the chamber) and then decreases (to the right of the axis Z, i.e. downstream of the centre of the chamber).

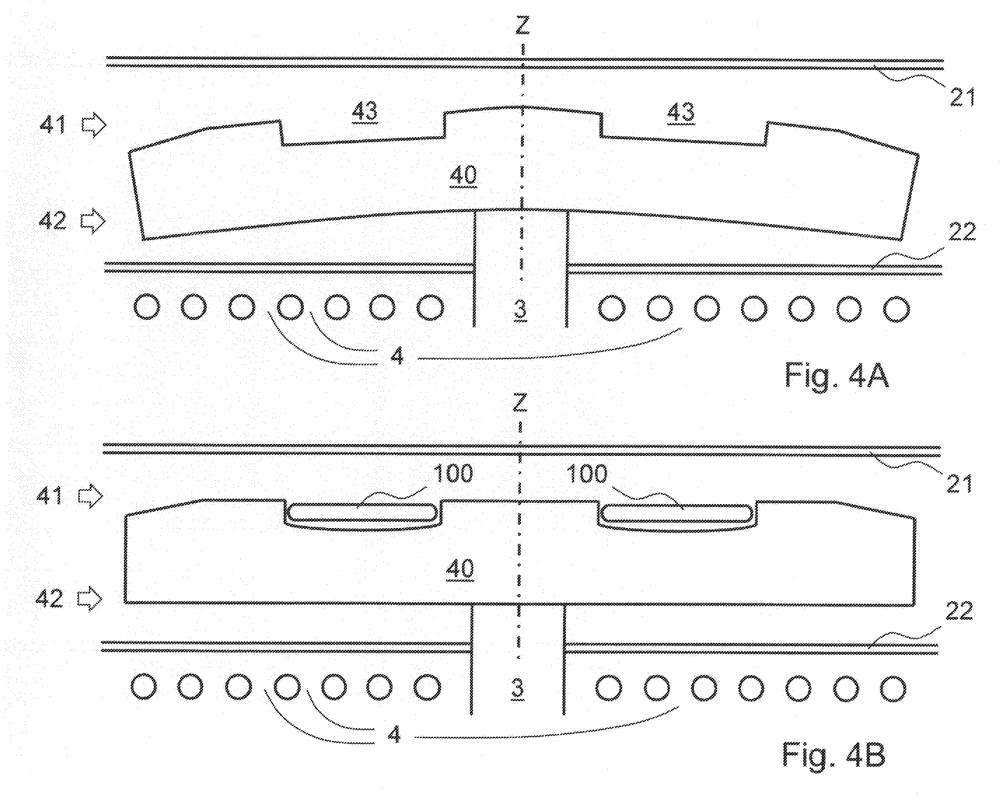

FIG. 4 shows a susceptor 40 according to the disclosure inside a reaction chamber of an epitaxial reactor with “cold” walls (i.e. cooled through flows of gas and/or liquid); reference numeral 21 indicates the flat upper wall of the chamber and reference numeral 22 indicates the flat lower wall of the chamber; the susceptor 40 is mounted on a rotating shaft 3. The heating system of the susceptor 40 is by induction and is obtained through a flat inductor 4 arranged outside of the chamber under the lower wall 22 and parallel to it.

The susceptor 40 consists of a substantially cylinder-shaped body made of graphite totally coated, for example, with SiC; the body has a first upper face 41, a second lower face 42 and a vertical axis Z of substantially symmetry of the body; the first upper face has a plurality (typically between two and eight) of thin substantially disc-shaped recesses 43 in which substrates 100 are housed and laid down; the recesses have a slightly concave bottom and therefore, when cold, a substrate 100 touches the bottom of the recess only in an annular area.

FIG. 4A shows the susceptor 40, without substrates, inside the reaction chamber at low temperature; FIG. 4B shows the susceptor 40, with substrates 100, inside the reaction chamber when the deposition on the substrates 100 begins (i.e. at high temperature) and during the deposition on the substrates 100 (i.e. at high temperature); note the deformation of the susceptor 40 and the consequent deformation (and movement) of the recesses 43 thereof; the substrates 100 also deform, as described earlier.

The susceptor 40 is suitably configured—one could say “pre-deformed”—(see FIG. 4A) so that when the conditions for epitaxial deposition are reached in the reaction chamber, the susceptor has deformed and its recesses have taken up the shape and position equal or very similar to the ideal ones (see FIG. 4B).

The deformed susceptor of FIG. 4B is such that the contact between substrates and susceptor (inside the recesses) is regular and causes uniform heating of the substrates.

Moreover, the deformed susceptor of FIG. 4B is such that the substrates are in perfectly flat position.

Finally, the deformed susceptor of FIG. 4B does not create turbulence along the path of the gases inside the reaction chamber since the distance between susceptor and upper wall of the chamber is uniform (both to the left of the axis Z, i.e. upstream of the centre of the chamber, and to the right of the axis Z, i.e. downstream of the centre of the chamber).

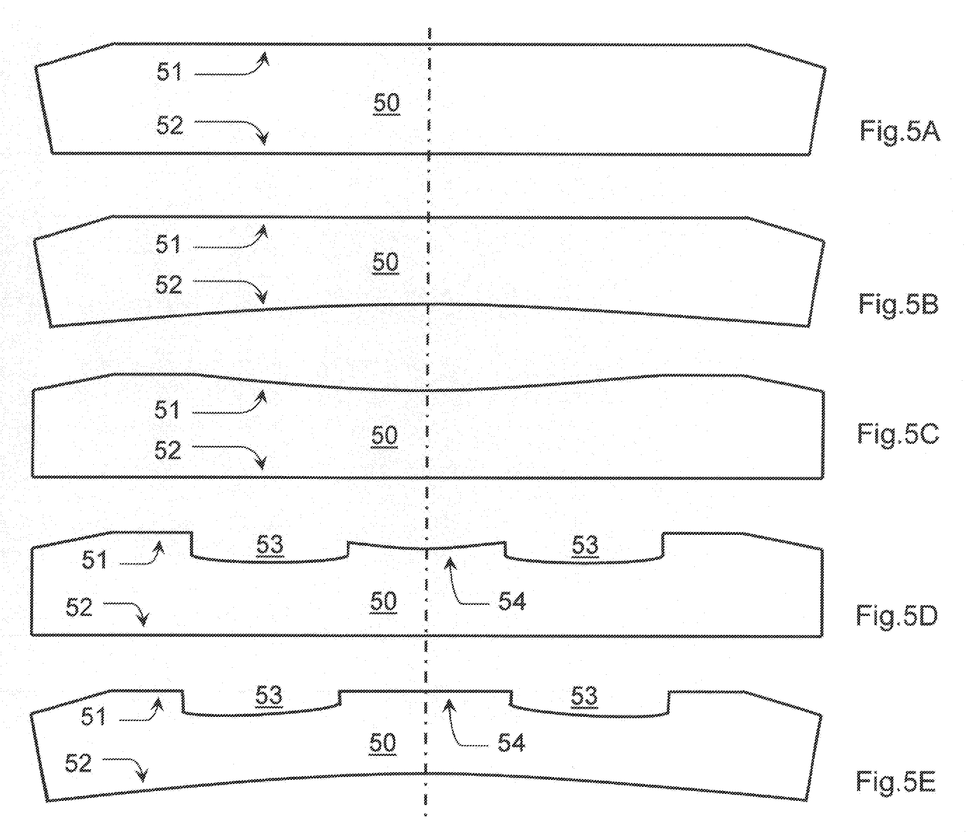

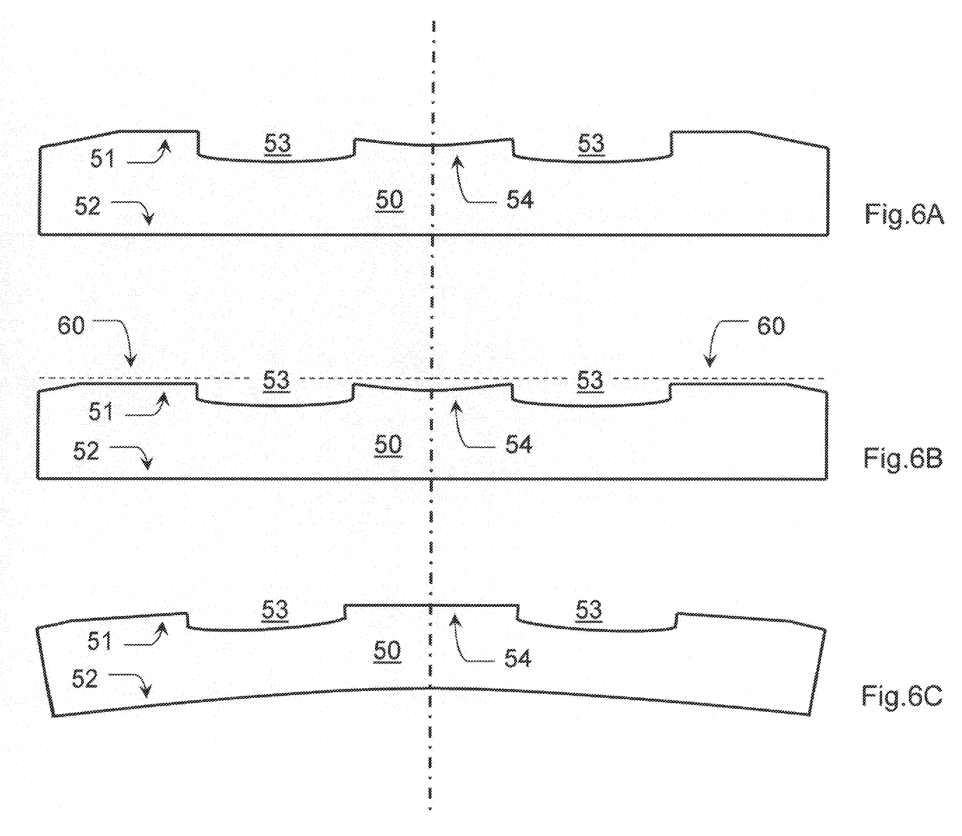

The expression “pre-deformed susceptor” does not necessarily mean that a susceptor is taken, it is deformed, it is worked and it is used in a reaction chamber. This is a constructive possibility that will be illustrated with the help of FIG. 5 and FIG. 6.

But there are other constructive possibilities.

For example, a susceptor like that of FIG. 4A could be made through mechanical processing, in particular milling, of a piece of graphite.

For example, a susceptor like that of FIG. 4A could be made by sintering a piece of graphite.

These last two processes are possible in cases in which the deformation that the susceptor (together with its recesses) undergoes when it is in the reaction chamber is determined a priori; this can be done through computerised simulation or through experimental testing.

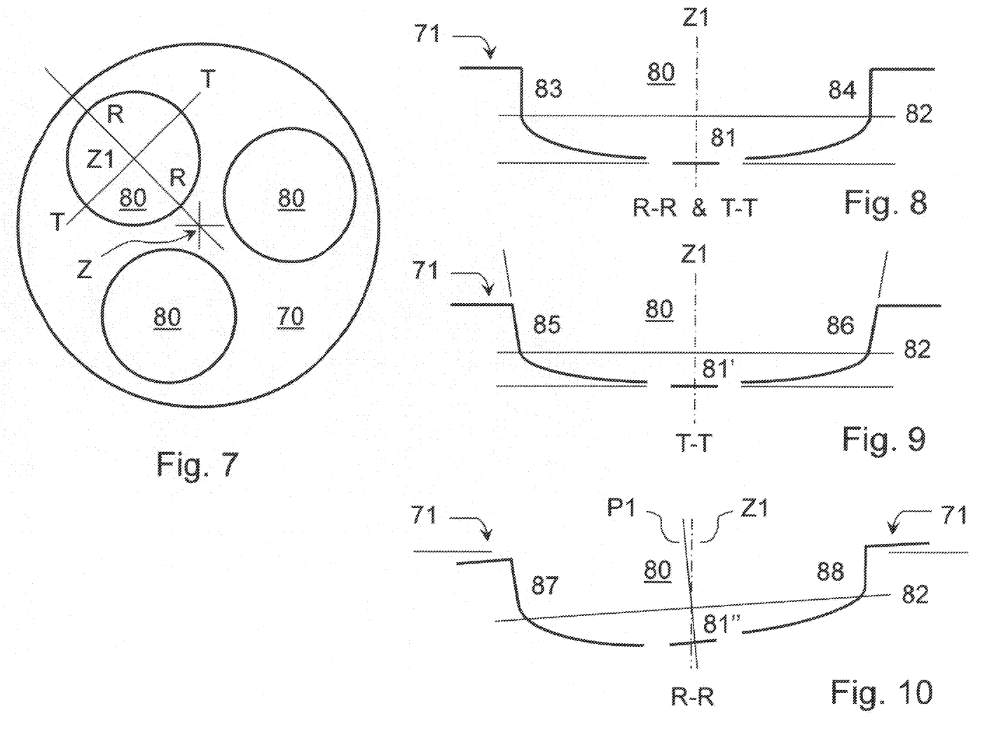

FIGS. 7 to 10 make it possible to understand the shape, in general, of the “pre-deformed susceptor” recesses, i.e. at low temperature inside a reaction chamber or outside of a reaction chamber.

FIG. 7 shows a susceptor according to the disclosure that consists of a disc-shaped body 70, a vertical axis Z of substantial symmetry of the body and, for example, three recesses 80 that are equal and arranged symmetrically with respect to the axis Z.

The body of the susceptor according to the disclosure deforms by lifting its outer edge (as shown in FIG. 3 and in FIG. 4), the vertical section according to the “tangential plane” T-T of FIG. 9 (which passes through the centroid of a recess) transforms into that of FIG. 8 (“ideal tangential section”) and the vertical section according to the “radial plane” R-R of FIG. 10 (which passes through the centroid of a recess) transforms into that of FIG. 8 (“ideal radial section”); here, the term “tangential plane” defines any vertical plane that is parallel to the vertical axis Z of symmetry of the body of the susceptor and that is perpendicular to the radius of the body of the susceptor passing through the centroid of the recess; here, the term “radial plane” defines any vertical plane that comprises the vertical axis Z of symmetry of the body of the susceptor.

The recess 80 of FIG. 8 (“ideal tangential section” and “ideal radial section” of the recesses of the susceptor) has a shape corresponding to a thin cylinder placed over a thin spherical cap; a horizontal plane 82 separates cylinder and cap from one another, and contains the base of the cap and one of the two bases of the cylinder; the diameter of the base of the cap corresponds to the diameter of the base of the cylinder; like in FIG. 8, the side surface of the cylinder can be joined to the surface of the cap, i.e. to the cap; the surface around the recess 80 of the upper face 71 is flat and horizontal.

The profile of the recess of FIG. 8 consists of a continuous line comprising in succession a first vertical segment 83, an arc of circumference 81 and a second vertical segment 84; like in FIG. 8, the arc 81 is joined on one side to the segment 83 and on the other side to the segment 84.

It should be noted that FIG. 8 corresponds to the section of the recess according to the vertical plane R-R in FIG. 7, the vertical plane T-T in FIG. 7 and any other vertical plane that passes through the centroid of the recess 80 (and therefore through the axis Z1 of symmetry of the recess 80 when the axis if vertical).

The shape of the recess of FIG. 8 corresponds to the “ideal” or “nominal” shape of the recess.

According to alternative solutions, the recess could have a shape corresponding, for example, to a first thin upper cylinder sitting over a second thin lower cylinder (the diameter of the lower cylinder is smaller than the diameter of the upper cylinder) sitting over a thin spherical cap.

The recess 80 of FIG. 8 corresponds to the deformation of the recess 80 of FIG. 9 and FIG. 10; the recess 80 (or rather each recess of the susceptor) deforms since the disc-shaped body 70 of the susceptor where it is located deforms; the entire edge of the disc-shaped body 70 of the susceptor bends (slightly) upwards whereas the centroid of the disc-shaped body 70 of the susceptor stays still (being constrained in particular to a drive shaft with vertical axis corresponding to the axis Z in FIG. 7).

The profile of the recess of FIG. 9 consists of a continuous line comprising in succession a first segment 85 that is slightly inclined, an arc of circumference 81′ and a second segment 86 that is slightly inclined; the projection of the plane 82 is horizontal; the surface around the recess 80 of the upper face 71 is flat and horizontal.

The profile of the recess of FIG. 10 consists of a continuous line comprising in succession a first segment 87 that is slightly inclined, an arc of curve 81″ and a second segment 88 that is almost vertical; such an arc is slightly wider on the left than on the right; the projection of the plane 82 is slightly inclined; the surface around the recess 80 of the upper face 71 is flat and slightly inclined; the axis P1 that passes through the centroid of the recess and is perpendicular to the plane 82 is slightly inclined with respect to the vertical axis Z1 that passes through the centroid of the recess.

The susceptor according to the disclosure (consider, for example, FIG. 4, FIG. 7, FIG. 8, FIG. 9 and FIG. 10) comprises a substantially disc-shaped body (40 in FIG. 4) that is adapted for being arranged horizontally; the body is typically made of graphite and is typically totally or partially coated with SiC and/or TaC; the body (40 in FIG. 4) has a first upper face (41 in FIG. 4), a second lower face (42 in FIG. 4) and a vertical axis (Z in FIG. 4) of substantial symmetry of the body; the first face (41 in FIG. 4) has a plurality of thin substantially disc-shaped recesses (43 in FIG. 4, 80 in FIG. 7-10) each with a centroid and with an axis (Z1 in FIG. 7-10) of substantial symmetry of the recess that passes through the centroid. When cold, a section (FIG. 10) of each of the recesses (80 in FIG. 7-10) according to any vertical “radial plane” (for example R-R in FIG. 7-10) is asymmetrical with respect to any axis (for example Z1 in FIG. 7-10), in particular the “radial plane” that passes through the centroid of the recess. When cold, a section (FIG. 9) of each of said recesses (80 in FIG. 7-10) according to any vertical “tangential plane” (for example T-T in FIG. 7-10) is symmetrical with respect to a vertical axis (i.e. Z1 in FIG. 7-10), in particular the “tangential plane” that passes through the centroid of the recess.

Here, the term “tangential plane” is meant to define any vertical plane that is parallel to the vertical axis Z of symmetry of the body of the susceptor and that is perpendicular to the radius of the body of the susceptor passing through the centroid of the recess; here, the term “radial plane” is meant to define any vertical plane that comprises the vertical axis Z of symmetry of the body of the susceptor.

In the example of FIG. 4 and FIG. 7-10, each of the recesses 80 has a bottom 81 associated substantially with a plane 82; when cold, the plane 82 is not perpendicular to the vertical axis (Z) of substantial symmetry of the body 70 that is adapted for being perpendicular (see FIG. 9 and FIG. 10 in combination).

Specifically, in the “radial plane” that passes through the centroid of the recess, (see FIG. 10) the angle comprised between P1 and any vertical axis (in particular Z1) is different from 0° and is in particular comprised in the range 1°-5° ; in other words, the vertical axis Z1 is not (substantially) perpendicular to the projection of the plane 82.

Specifically, in the “tangential plane” that passes through the centroid of the recess, (see FIG. 9) the angle comprised between P1 and any vertical axis (in particular Z1) is about 0°; in other words, the vertical axis Z1 is (substantially) perpendicular to the projection of the plane 82.

In the example of FIG. 4 and FIG. 7-10, the first upper face 41 is flat or slightly convex.

In the example of FIG. 4 and FIG. 7-10, the second lower face 42 is flat or slightly concave.

In the example of FIG. 4 and FIG. 7-10, the recesses 80 of the plurality are equal and located in symmetrical positions with respect to the vertical axis Z of substantial symmetry.

In the example of FIG. 4 and FIG. 7-10, the recesses 80 of the plurality have a flat or slightly concave bottom 81.

In the example of FIG. 4 and FIG. 7-10, the recesses 80 of the plurality have a full bottom 81, i.e. the bottom is a continuous surface without recesses or holes.

Disc-shaped susceptors like those described above are typically to be used in reaction chambers with “cold” walls of epitaxial reactors, in particular for the deposition of silicon on silicon substrates, with induction heating.

FIG. 5 illustrates, in successive steps, a possible method for producing a susceptor according to the disclosure. The recesses of FIG. 5D have the “perfect” shape (i.e. with “nominal” dimensions) and result in a “perfect” position of the substrates (i.e. with “nominal” position), in particular perfectly horizontal.

The idea forming the basis of this method consists of artificially creating a mechanical deformation of the susceptor that is to the greatest possible extent equal and opposite to the deformation (thermal and electromagnetic) that the susceptor undergoes when it is located in the reaction chamber; the recesses are dug into the susceptor thus deformed.

FIG. 6 is to describe a possible variant of the method of FIG. 5.

The method according to the disclosure (consider, for example, FIG. 5) comprises the following steps in sequence:
A) (FIG. 5A) providing a disc-shaped body (50), typically with cylindrical symmetry, made of graphite preferably with elastic properties, with a first face (51) and a second face (52),
B) (FIG. 5B) digging into said disc-shaped body (50) (entirely or at least for 70-80% of the area of the second face and in any case centrally with respect to the vertical axis of symmetry of the body) so as to shape the surface of the second face (52) like a cap, in particular a spherical cap,
   (steps A and B could be integrated, i.e. the body could already be equipped with a cap on the back)
C) (FIG. 5C) applying a typically mechanical deforming action to said dug disc-shaped body (50) so that the surface of the second face (52) becomes flat,
   (the dug and deformed disc-shaped body maintains a cylindrical symmetry)
D) (FIG. 5D) digging out said disc-shaped body (50) so as to form a plurality of thin substantially disc-shaped recesses (53) in the first face (51),
   (the vertical axis of cylindrical symmetry of the recesses is parallel to the vertical axis of cylindrical symmetry of the deformed disc-shaped body)
   (the bottom of the recesses is typically full and concave),
and
E) (FIG. 5E) removing said deforming action from said disc-shaped body (50). Preferably, said deforming action is obtained by means of depression.

After step E, said disc-shaped body can be totally or partially coated with SiC and/or TaC.

According to a first variant of the method of FIG. 5, a levelling of the first face is carried out.

According to a first alternative of such a first variant, immediately before step E, said disc-shaped body is dug into so as to level the first face, as can be seen in FIG. 6; FIG. 6A corresponds to FIG. 5D; in FIG. 6B, the first face 51 is levelled according to a plane 60, but the recesses 53 are not eliminated, but rather are maintained ensuring that their edge has substantially the same height all over; in FIG. 6C, the deforming action is removed from the disc-shaped body.

According to a second alternative of such a first variant (that facilitates the digging of the recesses), the levelling is done immediately after step C instead of immediately before step E, i.e. before having dug the recesses.

According to a second variant of the method of FIG. 5 (not shown in any of the figures), the second flat face (52) is not dug into, but a typically mechanical deforming action (preferably obtained by means of depression) is applied to the disc-shaped body so that the surface of the second face becomes a cap, in particular a spherical cap.

Instead of levelling the first face (51) of the body of the susceptor, it could be shaped right from the start of the method so that the edge of the recesses has substantially the same height all over when the recesses are then dug.

It should be noted that the central area (54) of the first face (51) of the body of the susceptor produced as described above could not be perfectly flat during the treatment processes of the substrates.

By using production methods like those described above, susceptors according to the disclosure are obtained.

As already stated, susceptors according to the disclosure can also be obtained by milling or sintering.

1. Susceptor comprising a body having the shape of a horizontal disc, wherein said body has a first upper face, a second lower face and a vertical symmetry axis of the body, wherein said first face has a plurality of disc-shaped recesses, each of which with a centroid and with a symmetry axis of the recess which passes through said centroid;
wherein a section of each of said recesses taken along any vertical plane which comprises said vertical symmetry axis of the body is asymmetric with respect to any axis;
wherein a section of each of said recesses taken along any vertical plane which is parallel to said vertical symmetry axis of the body and which is perpendicular to a radius of the body passing through the centroid of the recess is symmetric with respect to a vertical axis.

2. Susceptor according to claim 1, wherein each of said recesses has a bottom associated with a plane, said plane being non-perpendicular to said vertical symmetry axis of the body.

3. Susceptor according to claim 1, wherein said first upper face is either flat or convex.

4. Susceptor according to claim 1, wherein said second lower face is either flat or concave.

5. Susceptor according to claim 1, wherein the recesses of said plurality are equal and located in symmetric positions with respect to said vertical symmetry axis.

6. Susceptor according to claim 1, wherein the recesses of said plurality have an either flat or concave bottom.

7. Susceptor according to claim 1, wherein the recesses of said plurality have a bottom which is a continuous surface.

8. Reactor for epitaxial deposition comprising at least one susceptor according to claim 1.

9. Method for producing a susceptor, comprising the following steps in sequence:
A) providing a disc-shaped body made of graphite with a first face and a second face,
B) excavating said disc-shaped body so as to shape the surface of the second face as a cap,
C) applying a deforming action to said excavated disc-shaped body so that the surface of the second face becomes flat,
D) excavating said disc-shaped body so as to obtain a plurality of substantially disc-shaped recesses in the first face, and
E) removing said deforming action from said disc-shaped body.

10. Method according to claim 9, wherein said deforming action is obtained by means of depression.

11. Method according to claim 9, wherein after step E said disc-shaped body is either totally or partially coated with TaC and/or SiC.

12. Method according to claim 9, wherein after step E said disc-shaped body is excavated so as to flatten the first face.

13. Method for producing a susceptor, comprising the following steps in sequence:
A) providing a disc-shaped body made of graphite with a first face and a second flat face,
B) applying a deforming action to said disc-shaped body so that the surface of the second face becomes a cap,
C) excavating said disc-shaped body so as to obtain a plurality of substantially disc-shaped recesses in the first face, and
D) removing said deforming action from said disc-shaped body.

14. Method according to claim 13, wherein said deforming action is obtained by means of depression.

15. Method according to claim 13, wherein after step D said disc-shaped body is either totally or partially coated with TaC and/or SiC.

16. Method according to claim 13, wherein before step D said disc-shaped body is excavated so as to flatten the first face.
